(19) United States
(12) Patent Application Publication
(10) Pub. No.: US 2022/0118631 A1
(43) Pub. Date: Apr. 21, 2022

(54) HEAD OF A CHIP PICKER

(71) Applicant: Powertech Technology Inc., Hukou Township (TW)

(72) Inventors: Wu-Yi CHOU, Hukou Township (TW); Kun-Chi HSU, Hukou Township (TW); Chin-Ta WU, Hukou Township (TW); Yung-Chin SHIH, Hukou Township (TW); Chin Cheng LIU, Hukou Township (TW); Jentung TSENG, Hukou Township (TW)

(73) Assignee: Powertech Technology Inc., Hukou Township (TW)

(21) Appl. No.: 17/183,752

(22) Filed: Feb. 24, 2021

(30) Foreign Application Priority Data
Oct. 16, 2020 (TW) 109135982

(51) Int. Cl. B25J 15/06; H01L 21/683

(52) U.S. Cl. CPC B25J 15/0691; H01L 21/6838

(57) ABSTRACT

A head of chip picker is disclosed. The head has a clipping seat and an elastic block. The clipping seat has a body and two arms. The arms are respectively and downwardly extended from two opposite sides of an inner top surface of the body, so a cavity with a wide-top and narrow-bottom shape is constituted among the inner top surface and the arms. The elastic block matches the cavity and is laterally inserted into the cavity. The elastic block is not deformed after inserting into the cavity and provides a flat bottom surface.

### CROSS-REFERENCE TO RELATED APPLICATIONS

This application is based upon and claims priority under 35 U.S.C. 119 from Taiwan Patent Application No. 109135982 filed on Oct. 16, 2020, which is hereby specifically incorporated herein by this reference thereto.

### BACKGROUND OF THE INVENTION

### 1. Field of the Invention

The present invention is related to a head of a chip picker, and more particularly to a new head of chip picker.

### 2. Description of the Prior Arts

In the semiconductor packaging procedure, a head 30 of chip picker is used. The head 30 has a clipping seat 31 and an elastic block 32. The clipping seat 31 has four arms 311 and a cavity 300 is constituted among the arms 311. The elastic block 32 is tightly fitted into the cavity 300 from a bottom of the cavity 300.

The elastic block 32 is larger than cavity 300 to avoid falling from the bottom of the cavity 300, so the elastic block 32 is deformed after fitted in the cavity 300. Therefore, as shown in FIG. 6, a lower surface 321 of the elastic block 32 is convex but not flat.

Since the chips are thinner, the thinner chips are easily damaged when the convex surface 321 of the elastic block 32 touches the thinner chip and picks it up.

To overcome the shortcomings, the present invention provides a new head of chip picker to mitigate or to obviate the aforementioned problems.

### SUMMARY OF THE INVENTION

An objective of the present invention is to provide a new head of chip picker to obviate the aforementioned problems.

To achieve the objective as mentioned above, the head of a chip picker has a clipping seat and an elastic block. The clipping seat has a body and two first arms. The body has an inner top surface and a vacuum hole. The two first arms are respectively and downwardly extended from two opposite sides of the inner top surface and a cavity with a wide-top and narrow-bottom shape is constituted among the inner top surface and the two opposite first arms. The vacuum hole communicates with the cavity. The elastic block matches and fits into the cavity and has a top surface, a flat bottom surface, two first sides and a plurality of through holes. The top surface is flatly mounted on the inner top surface of the body of the clipping seat. The flat surface is protruding from a bottom of the cavity. The two first sides are respectively flatly mounted on two inner walls of the two first arms. The through holes are formed through the top surface and the flat bottom surface of the elastic block and communicates with the cavity.

Based on the foregoing description, the head of the chip picker of the present invention has the cavity with the wide-top and narrow-bottom shape constituted by the two first arms and the body of the clipping seat. Since the elastic block matches the cavity, the elastic block laterally inserts into the cavity and is received in the cavity. The elastic block is not deformed after inserting into the cavity and provides the flat bottom surface. The elastic block is not fallen from the bottom of the cavity.

Other objectives, advantages and novel features of the invention will become more apparent from the following detailed description when taken in conjunction with the accompanying drawings.

### BRIEF DESCRIPTION OF THE DRAWINGS

FIG. 1 first embodiment of a head of a chip picker in accordance with the present invention;

FIG. 2 is a perspective exploded view of FIG. 1;

FIG. 3 is a second embodiment of a head of a chip picker in accordance with the present invention;

FIG. 4 is a side view of Figl;

FIG. 5 is a perspective exploded view of a conventional head of chip picker in accordance with the prior art; and

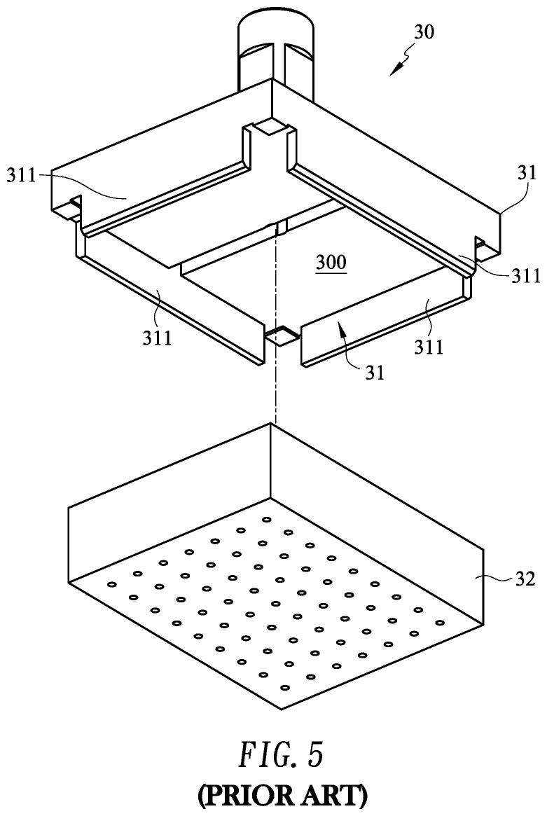

FIG. 6 is a side view of the head as shown in FIG. 5.

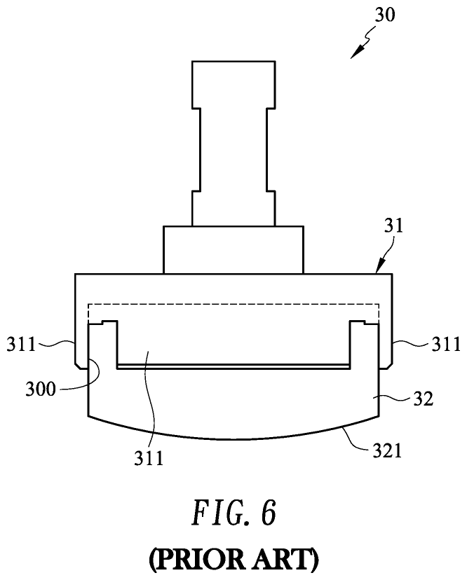

### DETAILED DESCRIPTION OF THE EMBODIMENTS

The present invention relates to a head of a chip picker used in a semiconductor package procedure. With embodiments and drawings thereof, the features of the present invention are described in detail as follow.

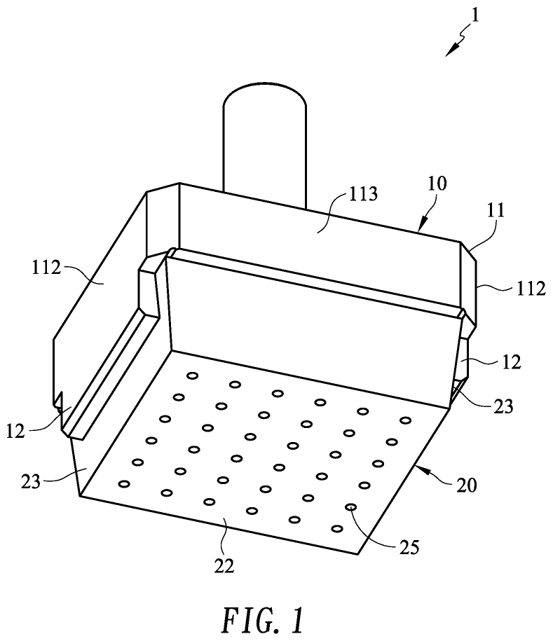

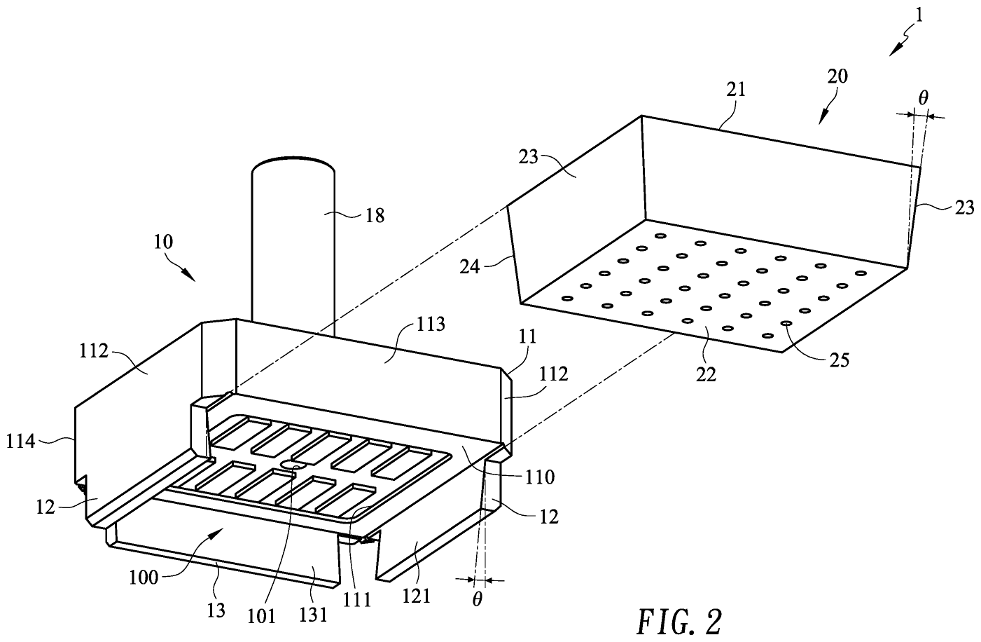

With reference to FIGS. 1 and 2, a first embodiment of a head of chip picker of the present invention is shown. The head 1 has a clipping seat 10 and an elastic block 20. The clipping seat 10 has a cavity 100 with a wide-top and narrow-bottom shape. The elastic block 20 matches the cavity 100, so the elastic block 20 is made of a wide-top and narrow-bottom shape.

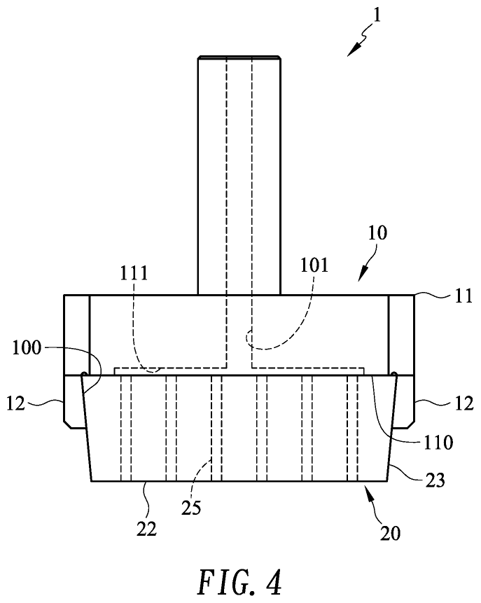

The clipping seat 10 has a body 11 and two first arms. The body 11 has an inner top surface 110 and a vacuum hole 111 formed on the inner top surface 110. The two first arms 12 are respectively and downwardly extended from two opposite first sides 112 of the inner top surface 110. Each of the first arms 12 has an inner incline wall 121. The inner inclined wall 121 is inwardly inclined from top to bottom according to an inclination angle θ. The inclination angle 0 is defined between the inner top surface 110 of the body 11 of the clipping seat 10 and a normal line thereof. Therefore, with reference to FIG. 4, the cavity 100 is constituted among the inner top surface 110 and the two first arms 12 and formed of the wide-top and narrow-bottom shape. The vacuum hole 101 communicates with the cavity 100. In the present embodiment, the vacuum hole 101 is formed on a center area of the inner top surface 110 and an air channel 111 is formed on the rest area of the inner top surface. The vacuum hole 101 communicates with the air channel 111. In the present embodiment, the air channel is shaped of a grid.

The elastic block 20 is inserted into the cavity 100 from a second side 113 of the body 11 of the clipping seat 10. Two opposite first sidewalls 23 of the elastic block 20 corresponding to the first arms 12 are inwardly inclined from top to bottom according to the same inclination angle θ. With reference to FIG. 4, the elastic block 20 has a top surface 21, a flat bottom surface 22 and a plurality of through holes 25. The top surface 21 is flatly mounted on the inner top surface 21 and the flat bottom surface 22 is protruding from a bottom of the cavity 100. A height of the elastic block 20 is larger than that of each first arm 12. The through holes 25 are formed through the top surface 21 and the flat bottom surface 22 of the elastic block 20 and communicates with the vacuum hole 101 and air channel 111. In the present embodiment, the through holes 25 are formed in matrix and the elastic block 20 is made of rubber.

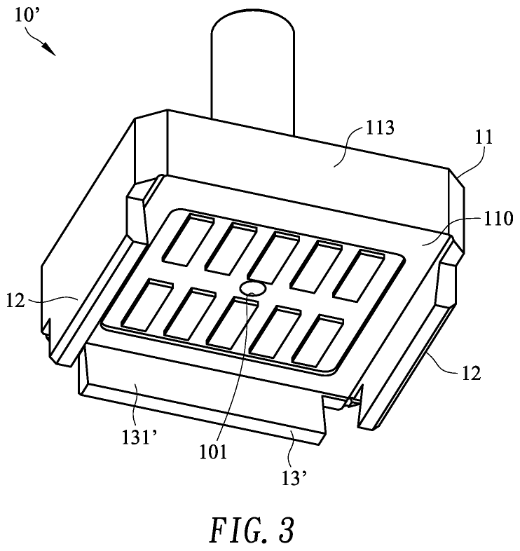

With reference to FIG. 2, a second arm 13 is downwardly extended from a third side 114 of the inner top surface 110 of the body 11. When the elastic block 20 is laterally inserted into the cavity 100 from the second side 113 and then touches the third side 114 opposite to the second side 113, the elastic block 20 is completely received in the cavity 100. In the present embodiment, an inner wall 131 of the second arm 13 may be vertical relative to the inner top surface 110 but not inclined. With reference to FIG. 3, a clipping seat 10′ of a second embodiment is shown. An inner wall 131′ of a second arm 13 may be inwardly inclined from top to bottom according to an inclination angle θ. A second sidewall 24 of the elastic block 20 corresponding to the second arm 13′ is inwardly inclined from top to bottom according to the same inclination angle θ. In one embodiment, four sidewalls of the elastic block 20 may be inwardly inclined from top to bottom according to the same inclination angle θ.

With reference to FIG. 2, since the elastic block 20 matches the cavity 100, the elastic block 20 laterally is inserted into the cavity 100 and received in the cavity 100. At the time, the flat bottom surface 22 of the elastic block 20 is still flat. Since the cavity 100 has a wide top and a narrow bottom, the elastic block 20 is not fallen from the narrow bottom of the cavity 100.

Based on the foregoing description, the flat bottom surface of the elastic block is not deformed and is still flat after the elastic block is received in the cavity. When the head picks up the chip, the flat bottom surface of the elastic block touches the chip, and the chip is not easily damaged. Furthermore, since the cavity is formed of the wide-top and narrow-bottom shape, the elastic block is easily received into the cavity.

Even though numerous characteristics and advantages of the present invention have been set forth in the foregoing description, together with details of the structure and features of the invention, the disclosure is illustrative only. Changes may be made in the details, especially in matters of shape, size, and arrangement of parts within the principles of the invention to the full extent indicated by the broad general meaning of the terms in which the appended claims are expressed.

What is claimed is:

1. A head of a chip picker, comprising:
a clipping seat, comprising:
a body having an inner top surface and a vacuum hole formed on the inner top surface;
two first arms respectively and downwardly extended from two opposite first sides of the inner top surface of the body; and
a cavity with a wide-top and narrow-bottom shape defined between the inner top surface and the first arms and communicating with the vacuum hole; and
an elastic block matching and received in the cavity of the clipping seat and comprising:
a top surface flatly mounted on the inner top surface of the body;
a flat bottom surface protruding from a bottom of the cavity;
two first sidewalls respectively and flatly mounted on two inner sides of the first arms; and
a plurality of through holes formed through the top surface and the flat bottom surface and communicating with the vacuum hole.

2. The head of a chip picker as claimed in claim 1, wherein an inner wall of each of the first arm is inwardly inclined from top to bottom according to an inclination angle.

3. The head of a chip picker as claimed in claim 1, further comprising a second arm is downwardly extended from a second side of the inner top surface of the body.

4. The head of a chip picker as claimed in claim 2, further comprising a second arm is downwardly extended from a second side of the inner top surface of the body.

5. The head of a chip picker as claimed in claim 3, wherein an inner wall of the second arm is vertical relative to the inner top surface.

6. The head of a chip picker as claimed in claim 4, wherein an inner wall of the second arm is vertical relative to the inner top surface.

7. The head of a chip picker as claimed in claim 3, wherein an inner wall of the second arm is inwardly inclined from top to bottom according to the inclination angle.

8. The head of a chip picker as claimed in claim 4, wherein an inner wall of the second arm is inwardly inclined from top to bottom according to the inclination angle.

9. The head of a chip picker as claimed in claim 3, wherein an air channel is formed on the inner top surface of the body and communicates with the vacuum hole and the through holes of the elastic block.

10. The head of a chip picker as claimed in claim 4, wherein an air channel is formed on the inner top surface of the body and communicates with the vacuum hole and the through holes of the elastic block.

11. The head of a chip picker as claimed in claim 9, wherein the air channel is formed of a grid.

12. The head of a chip picker as claimed in claim 10, wherein the air channel is formed of a grid.

13. The head of a chip picker as claimed in claim 2, wherein two opposite first sidewalls of the elastic block corresponding to the first arms are inwardly inclined from top to bottom according to the inclination angle.

14. The head of a chip picker as claimed in claim 8, wherein two opposite first sidewalls of the elastic block corresponding to the first arms are inwardly inclined from top to bottom according to the inclination angle.

15. The head of a chip picker as claimed in claim 7, wherein a second sidewall of the elastic block corresponding to the second arm is inwardly inclined from top to bottom according to the inclination angle.

16. The head of a chip picker as claimed in claim 8, wherein a second sidewall of the elastic block corresponding to the second arm is inwardly inclined from top to bottom according to the inclination angle.

17. The head of a chip picker as claimed in claim 14, wherein a second sidewall of the elastic block corresponding to the second arm is inwardly inclined from top to bottom according to the inclination angle.

18. The head of a chip picker as claimed in claim 1, wherein the elastic block is made of rubber.
